(19) United States
(12) Patent Application Publication
(10) Pub. No.: US 2020/0098411 A1
(43) Pub. Date: Mar. 26, 2020

(54) SEMICONDUCTOR MEMORY DEVICE

(71) Applicant: TOSHIBA MEMORY CORPORATION, Tokyo (JP)

(72) Inventors: Hiroaki MAEKAWA, Yokohama Kanagawa (JP); Naoki MATSUSHITA, Yokohama Kanagawa (JP)

(73) Assignee: TOSHIBA MEMORY CORPORATION, Tokyo (JP)

(21) Appl. No.: 16/568,088

(22) Filed: Sep. 11, 2019

(30) Foreign Application Priority Data
Sep. 20, 2018 (JP) 2018-175977

(51) Int. Cl. G11C 11/16; G06F 3/06; H01L 27/22

(52) U.S. Cl. CPC G11C 11/1675; G06F 3/0604; G06F 3/0659; G11C 11/1659; H01L 27/228; G11C 11/161; G11C 11/1673; G06F 3/0679

(57) ABSTRACT

According to one embodiment, a semiconductor memory device includes a memory cell capable of storing data; a storage area including the memory cells; and a controller configured: to read data from the physical address in which write data will be write; to compare the read data and the non-inverted write data, and to calculate a number n1 of bits which require rewrite to first data when executing the write; to compare the read data and the inverted write data, and to calculate a number n2 of bits which require rewrite to the first data when executing the write; to compare the number n1 and the number n2; if n1≤n2, to write the non-inverted write data to the storage area; and if n1>n2, to write the inverted write data to the storage area.

### CROSS-REFERENCE TO RELATED APPLICATIONS

This application is based upon and claims the benefit of priority from prior Japanese Patent Application No. 2018-175977, filed Sep. 20, 2018; the entire contents of which are incorporated herein by reference.

### FIELD

Embodiments described herein relate generally to a semiconductor memory device.

### BACKGROUND

An MRAM (Magnetoresistive Random Access Memory) is a memory device which uses a magnetic element with a magnetoresistance effect as a memory cell which stores information. Attention is paid to the MRAM as a next-generation memory device having features of high-speed operation, large capacity and nonvolatility. In addition, the MRAM has been researched and developed as a substitute for a volatile memory such as a DRAM or SRAM. In this case, in order to suppress an increase in development cost and to smoothly carry out the substitution, it is desirable to operate the MRAM according to the same specifications as the DRAM and SRAM.

### BRIEF DESCRIPTION OF THE DRAWINGS

FIG. 1 is a block diagram illustrating a basic configuration of a memory system including a semiconductor memory device according to a first embodiment.

FIG. 2 is a block diagram illustrating a basic configuration of the semiconductor memory device according to the first embodiment.

FIG. 3 is a block diagram illustrating a basic configuration of a core of the semiconductor memory device according to the first embodiment.

FIG. 4 is a view illustrating a structure of data of one page.

FIG. 5 is a view illustrating a relationship between non-inverted write data and inverted write data.

FIG. 6 is a block diagram illustrating a basic configuration of a memory cell array of the semiconductor memory device according to the first embodiment.

FIG. 7 is a block diagram illustrating a first example of a configuration of a memory cell of the semiconductor memory device according to the first embodiment.

FIG. 8 is a block diagram illustrating a second example of the configuration of the memory cell of the semiconductor memory device according to the first embodiment.

FIG. 9 is a flowchart illustrating a write operation of the semiconductor memory device according to the first embodiment.

FIG. 10 is a view illustrating a concrete example of the write operation of the semiconductor memory device according to the first embodiment.

FIG. 11 is a flowchart illustrating a write operation of a semiconductor memory device according to a second embodiment.

FIG. 12 is a flowchart illustrating a write operation of a semiconductor memory device according to a third embodiment.

FIG. 13 is a flowchart illustrating a write operation of a semiconductor memory device according to a fourth embodiment.

FIG. 14 is a flowchart illustrating a write operation of a semiconductor memory device according to a fifth embodiment

### DETAILED DESCRIPTION

In general, according to one embodiment, a semiconductor memory device includes a memory cell capable of storing data; a storage area including the memory cells; and a controller configured: to read data from the physical address in which write data will be write, to compare the read data and the non-inverted write data, and to calculate a number n1 of bits which require rewrite to first data; to compare the read data and the inverted write data, and to calculate a number n2 of bits which require rewrite to the first data when executing the write; to compare the number n1 and the number n2; if n1<n2, to write the non-inverted write data to the storage area if n1≥n2 and to write the inverted write data to the storage area.

Hereinafter, embodiments, which are constituted, will be described with reference to the accompanying drawings. In the description below, structural elements having substantially the same function and structure are denoted by like reference numerals.

### <1> First Embodiment

<1-1> Configuration

<1-1-1> Configuration of Memory System

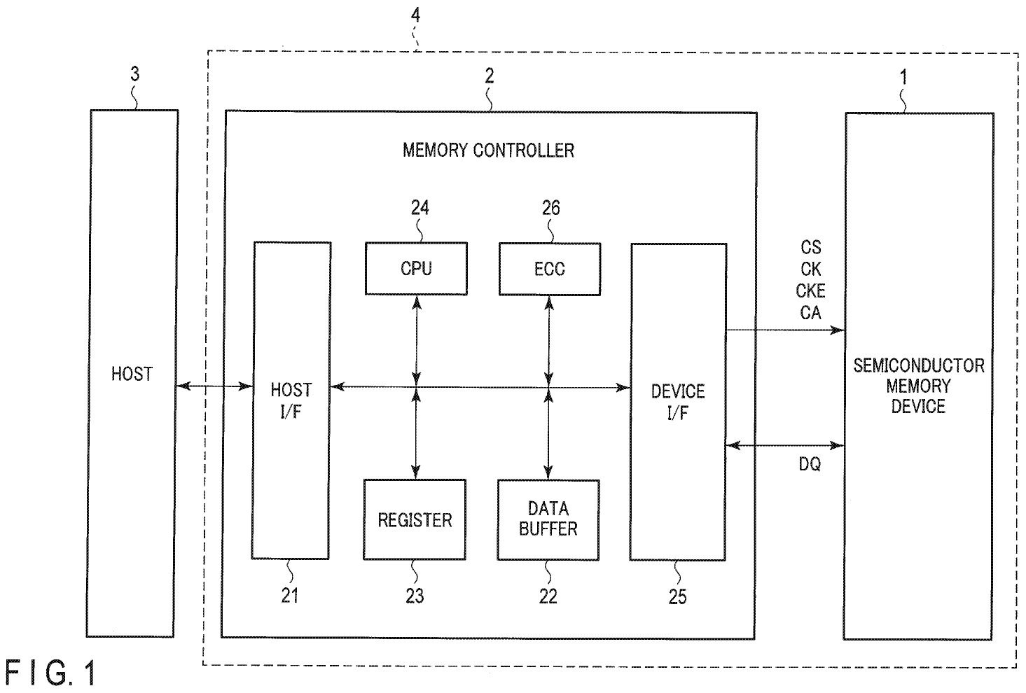

Referring to FIG. 1, a basic configuration of a memory system including a semiconductor memory device according to a first embodiment will be schematically described. A memory system 4 includes a semiconductor memory device 1 and a memory controller 2.

<1-1-2> Configuration of Memory Controller

The memory controller 2 receives instructions from a host (external equipment) 3 such as a personal computer, and reads data from the semiconductor memory device 1 and writes data to the semiconductor memory device 1.

The memory controller 2 includes a Host interface (I/F) 21, a data buffer 22, a register 23, a CPU 24, a Device Interface (I/F) 25, and an ECC circuit 26.

The host interface 21 is connected to the host 3. Transmission/reception of data is executed between the host 3 and memory system 4 via the host interface 21.

The data buffer 22 is connected to the host interface 21. The data buffer 22 receives data which was transmitted from the host 3 to the memory system 4 via the host interface 21, and temporarily stores the data. In addition, the data buffer 22 temporarily stores data which is to be transmitted from the memory system 4 to the host 3 via the host interface 21. The data buffer 22 may be a volatile memory or a nonvolatile memory.

The register 23 is, for example, a volatile memory, and stores setting information, commands, statuses, etc., which are executed by the CPU 24. The register 23 may be a volatile memory or a nonvolatile memory.

The CPU 24 controls the operation of the entirety of the memory system 4. The CPU 24 executes, for example, a predetermined process for the semiconductor memory device 1 in accordance with a command received from the host 3.

The device interface 25 executes transmission/reception of various signals between the memory controller 2 and semiconductor memory device 1.

The ECC circuit 26 receives write data which is received from the host 3 via the data buffer 22. Further, the ECC circuit 26 adds an error correcting code to the write data. The ECC circuit 26 supplies the error correcting code-added write data to, for example, the data buffer 22 or device interface 25.

Besides, the ECC circuit 26 receives data which is supplied from the semiconductor memory device 1 via the device interface 25. The ECC circuit 26 determines whether an error exists in the data received from the semiconductor memory device 1. When the ECC circuit 26 determines that an error exists in the received data, the ECC circuit 26 executes an error correction process on the received data by using the error correcting code. Then, the ECC circuit 26 supplies the error-corrected data to, for example, the data buffer 22, device interface 25, etc.

<1-1-3> Semiconductor Memory Device

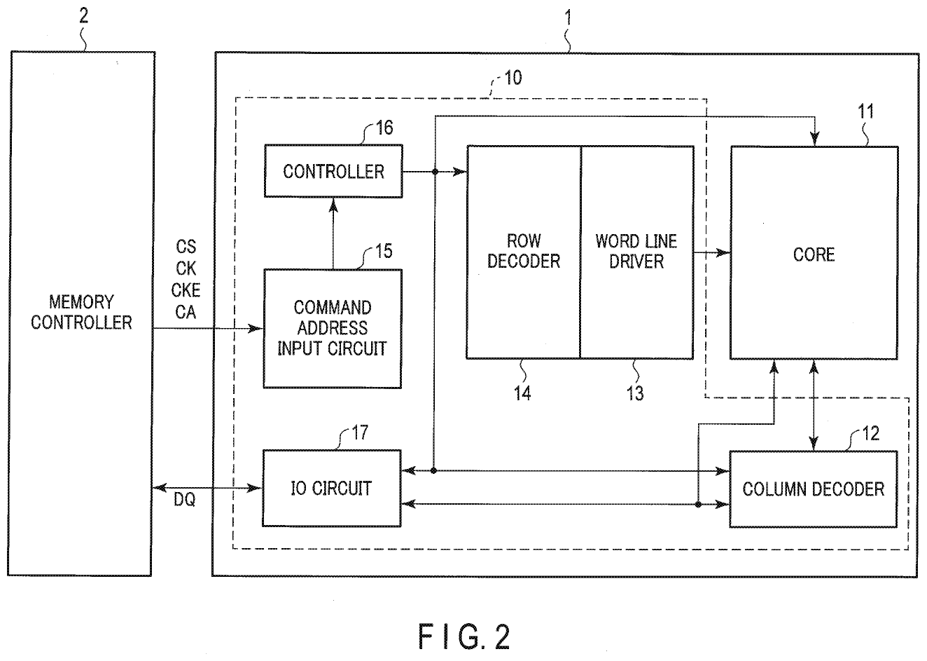

Referring to FIG. 2, a basic configuration of the semiconductor memory device according to the first embodiment will be schematically described.

The semiconductor memory device 1 according to the first embodiment includes peripheral circuitry 10 and a core 11.

The core 11 includes a memory cell array for storing data, etc. The details of the core 11 will be described later.

The peripheral circuitry 10 includes a column decoder 12, a word line driver 13, a row decoder 14, a command/address input circuit 15, a controller 16, and an IO circuit 17.

The column decoder 12 recognizes, based on an external control signal, a command or an address by a command/address signal CA, and controls selection of a bit line BL and a source line SL.

The word line driver 13 is disposed along at least one side of the memory cell array (to be described later). In addition, the word line driver 13 is configured to apply a voltage to a selected word line WL via a main word line MWL, at a time of data read or data write.

The row decoder 14 decodes an address of the command/address signal CA supplied from the command/address input circuit 15. More specifically, the row decoder 14 supplies a decoded row address to the word line driver 13. Thereby, the word line driver 13 can apply a voltage to the selected word line WL.

Various external control signals, for instance, a chip select signal CS, a clock signal CK, a clock enable signal CKE and command/address signal CA, are input to the command/address input circuit 15 from the memory controller (also referred to as “host device”). The command/address input circuit 15 transfers the command/address signal CA to the controller 16.

The controller 16 distinguishes a command and an address. The controller 16 controls the semiconductor memory device 1.

The IO circuit 17 temporarily stores input data which is input from the memory controller 2 via a data line DQ, or temporarily stores output data which is read from the core 11. The input data is written in memory cells of the core 11.

<1-1-4> Core

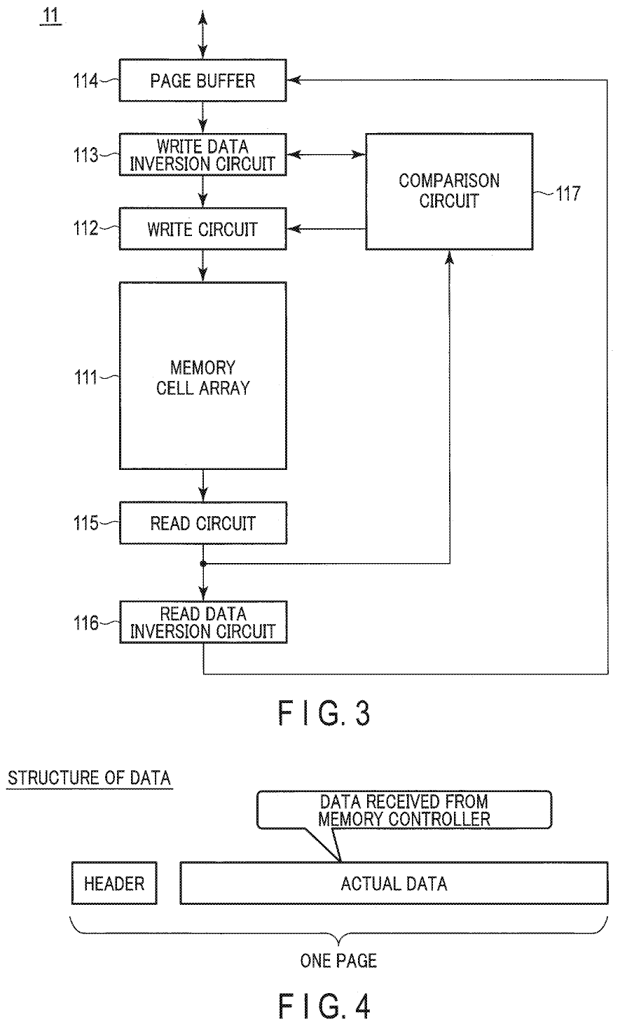

Referring to FIG. 3, the core 11 is described. The core 11 includes a memory cell array 111, a write circuit 112, a write data inversion circuit 113, a page buffer 114, a read circuit 115, a read data inversion circuit 116, and a comparison circuit 117.

The memory cell array 111 includes an array of magnetoresistance effect elements (memory cells). The details of the memory cell array 111 will be described later.

The page buffer 114 stores write data which is input via the IO circuit 17, and stores read data which is read from the memory cell array 111. Note that the data write and data read are executed in units of a plurality of memory cells (in units of a page). The unit of such batchwise write is called “page”. In the description below, write data for write, which is supplied via the IO circuit 17, is referred to as “non-inverted write data”.

Here, referring to FIG. 4, a structure of data of one page, which is written to the memory cell array 111, is described. The data structure of one page includes a header and actual data. The actual data is data of a plurality of bits, which is supplied from the memory controller 2. The header is composed of, for example, data of one bit, and is a bit indicating whether the actual data is write data itself (non-inverted write data) or inverted write data of the write data. For example, when the header is “0” data, this means that the actual data is non-inverted write data. When the header is “1” data, this means that the actual data is inverted write data.

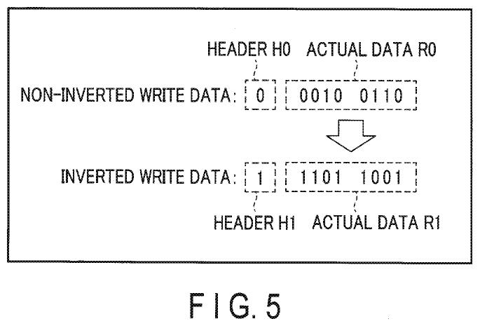

Referring back to FIG. 3, the core 11 will further be described. The write data inversion circuit 113 includes a function of transferring the non-inverted write data, which is stored in the page buffer 114, to the write circuit 112 as such, and a function of generating inverted write data in which the values of the bits of the non-inverted write data stored in the page buffer 114 are inverted (for example, “0” data, if inverted, becomes “1” data; “1” data, if inverted, becomes “0” data), and transferring the inverted write data to the write circuit 112. As illustrated in FIG. 5, when the write data inversion circuit 113 transfers the non-inverted write data (e.g. “0010 0110”) as such, the write data inversion circuit 113 sets the bit of the header of the data to “0” data. When the write data inversion circuit 113 transfers the inverted write data (e.g. “1101 1001”) in which the non-inverted write data is inverted, the write data inversion circuit 113 sets the bit of the header of the write data to “1” data.

The write circuit 112 includes a function of writing the write data to selected memory cells in the memory cell array 111.

The read circuit 115 includes a function of reading read data from selected memory cells in the memory cell array 111.

The read data inversion circuit 116 includes a function of transferring, when the bit of the header of read data is “0” data, the read data to the page buffer 114 as such, and a function of generating, when the bit of the header of read data is “1” data, inverted read data in which the values of the bits of the read data are inverted, and transferring the inverted read data to the page buffer 114.

Specifically, when the header of the data, which is read from the read circuit 115, is “0”, the read data inversion circuit 116 determines “non-inversion” for the read data, and supplies the read data to the page buffer 114 as such. On the other hand, when the header of the data, which is read from the read circuit 115, is “1”, the read data inversion circuit 116 determines “inversion” for the read data, inverts the bits of the read data, and supplies the inverted read data to the page buffer 114. In this manner, in the present embodiment, based on the header, it is understood whether the data is not to be inverted, or is to be inverted.

Concretely, the comparison circuit 117 includes at least one of the following functions:
a function of comparing non-inverted write data and read data and calculating a rewrite number L1 of “1” data (i.e. a number L1 of bits which require rewrite to “1” data),
a function of comparing inverted write data and read data and calculating a rewrite number L2 of “1” data,
a function of determining whether the rewrite number L2 is equal to or greater than the rewrite number L1,
a function of determining the header of write data,
a function of determining data which is to be actually written to the memory cell array 111, and
a function of comparing data that is to be actually written, and read data, enabling the write circuit 112 only at a time of writing different data, and disabling the write circuit 112 at a time of writing identical data.

<1-1-5> Memory Cell Array

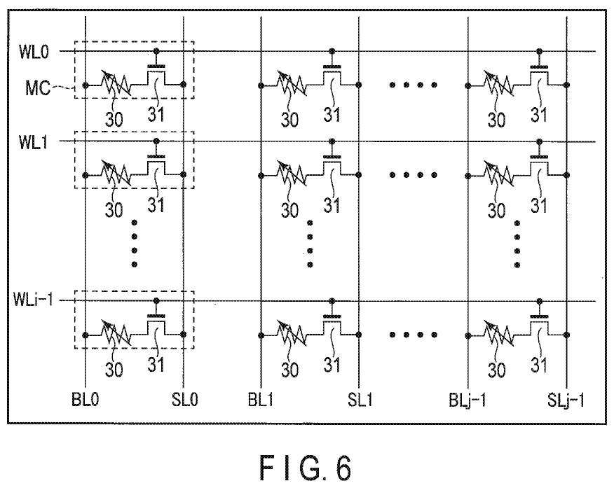

Referring to FIG. 6, a basic configuration of the memory cell array 111 of the semiconductor memory device according to the first embodiment will be schematically described.

The memory cell array 111 is configured such that a plurality of memory cells MC are arranged in a matrix. In the memory cell array 111, there are provided, a plurality of word lines WL0˜WLi−1 (i is an integer of 2 or more), a plurality of bit lines BL0˜BL−1 (j is an integer of 2 or more) and a plurality of source lines SL0˜SLj−1. One row of the memory cell array 111 is connected to one word line WL, and one column of the memory cell array 111 is connected to a pair composed of one bit line EL and one source line SL.

The memory cell MC is composed of a magnetoresistance effect element (MTJ (Magnetic Tunnel Junction) element) 30 and a select transistor 31. The select transistor 31 is composed of, for example, an N-channel MOSFET.

One end of the MTJ element 30 is connected to the bit line BL, and the other end of the MTJ element 30 is connected to the drain (source) of the select transistor 31. The gate of the select transistor 31 is connected to the word line WL, and the source (drain) of the select transistor 31 is connected to the source line SL.

<1-1-6> Memory Cell MC

### <1-1-6-1> First Example

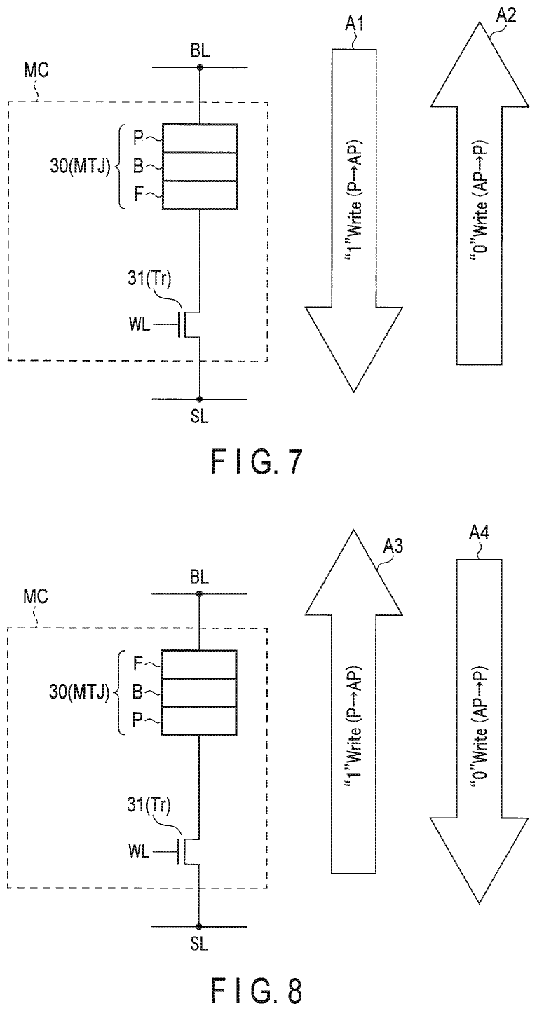

Next, referring to FIG. 7, a first example of the configuration of the memory cell MC of the semiconductor memory device according to the first embodiment will be schematically described. As illustrated in FIG. 7, one end of the MTJ element 30 of the memory cell MC according to the first embodiment is connected to the bit line BL, and the other end thereof is connected to one end of the select transistor 31. The other end of the select transistor 31 is connected to the source line SL. The MTJ element 30, which utilizes the TMR (tunneling magnetoresistance) effect, has a multilayer structure composed of two ferromagnetic layers F and P and a nonmagnetic layer (tunnel insulation film) B which is interposed between the ferromagnetic layers F and P. The MTJ element 30 stores digital data by a change of magnetic resistance due to a spin polarization tunnel effect. The MTJ element 30 can take a low resistance state and a high resistance state by a magnetization configuration of the two ferromagnetic layers F and P. For example, if the low resistance state is defined as data “0” and the high resistance state is defined as data “1”, 1-bit data can be recorded in the MTJ element 30. Needless to say, the low resistance state may be defined as data “1” and the high resistance state may be defined as data “0”.

For example, the MTJ element 30 is composed by successively stacking a storage layer (free layer, recording layer) F, a nonmagnetic layer B and a reference layer (pin layer, fixed layer) P. An artificial lattice made by stacking, for example, TbCoFe, Co, and Pt, a crystalline film made by regulating FePt to L10, or the like may be used for the reference layer P. In addition, by interposing CoFeB between the reference layer P and the nonmagnetic layer B, and as a result, it is possible to improve polarizability of the reference layer P, and to obtain a high MR ratio (magnetoresistive ratio).

The nonmagnetic layer B is made of a nonmagnetic material, and nonmagnetic metal, a nonmagnetic semiconductor, an insulator, and the like may be used for the nonmagnetic layer B. For example, the nonmagnetic layer B may be made of MgO. Since the nonmagnetic layer B is made of MgO, a high MR ratio may be obtained.

For example, the storage layer F may be made of CoFeB as a magnetic material. The storage layer F may have a stacked structure having two or more layers. In this case, for example, the storage layer F may have a stacked structure including two magnetic layers, the main components of which are CoFeB or CoFe, and a nonmagnetic metal layer interposed between the two magnetic layers.

The magnetization direction of the reference layer 30a (P) is non-variable (fixed). But the magnetization direction of the storage layer (F) is variable, and the storage layer F stores data in accordance with the direction of magnetization of the storage layer F.

When current is passed in the direction of an arrow A1 at a write time, the magnetization direction of the free layer F becomes antiparallel (AP state) to the magnetization direction of the reference layer P, and the free layer F enters a high resistance state (data “1”). When current is passed in the direction of an arrow A2 at a write time, the magnetization directions of the reference layer P and free layer F become parallel (P state), and the free layer F enters a low resistance state (data “0”). In this manner, different data can be written to the MTJ element in accordance with the direction of current that is passed. The above description “magnetization direction is variable” means that the magnetization direction is changed in accordance with a predetermined write current. On the other hand, the above description “magnetization direction is fixed” means that the magnetization direction is not changed in accordance with a predetermined write current.

### <1-1-6-2> Second Example

Next, referring to FIG. 8, a second example of the configuration of the memory cell MC of the semiconductor memory device according to the first embodiment will be schematically described. Only different points from the first example are described below. As illustrated in FIG. 8, in the second example, the MTJ element 30 is composed by successively stacking a reference layer (pin layer, fixed layer) P, a nonmagnetic layer B and a storage layer (free layer, recording layer) F.

When current is passed in the direction of an arrow A3 at a write time, the magnetization direction of the free layer F becomes antiparallel (AP state) to the magnetization direction of the reference layer P, and the free layer F enters a high resistance state (data “1”). When current is passed in the direction of an arrow A4 at a write time, the magnetization directions of the reference layer P and free layer F become parallel (P state), and the free layer F enters a low resistance state (data “0”).

In the description below, the semiconductor memory device will be described based on the first example of the configuration of the memory cell MC. In addition, it is assumed that the power consumption at a time of write to “1” data is greater than the power consumption at a time of write to “0” data.

<1-2> Operation

### <1-2-1> Operation Flow

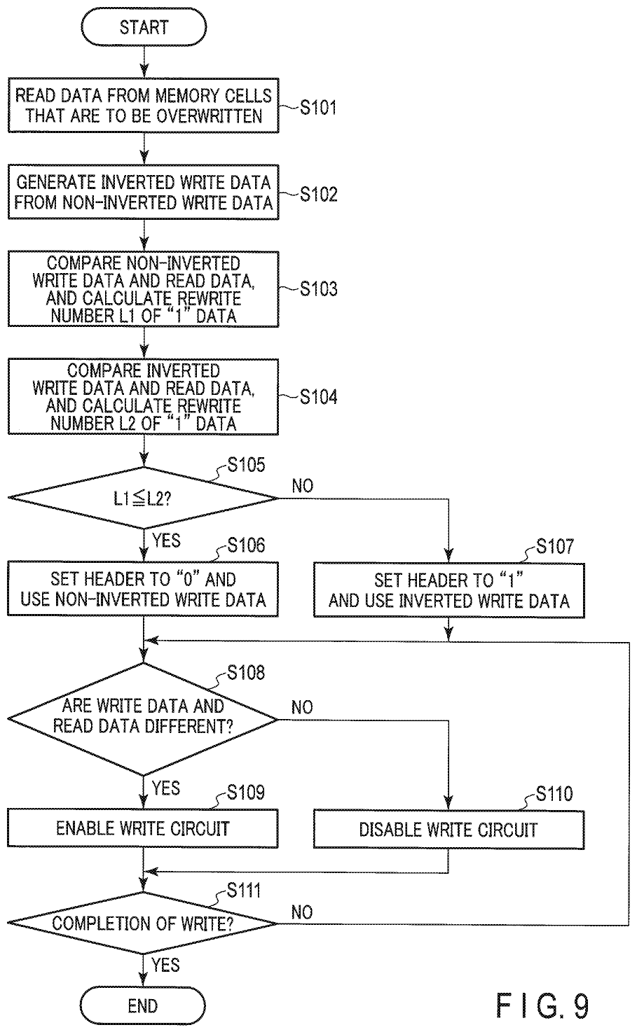

Hereinafter, referring to FIG. 9, a write operation of the semiconductor memory device according to the first embodiment will be described.

[Step S101]

When the controller 16 writes data to the memory cell array 111, the controller 16 first reads the data of the page, on which the data is overwritten. Specifically, the read circuit 115 reads data from selected memory cells. Further, the read data, which has been read, is stored in the comparison circuit 117.

[Step S102]

Non-inverted write data, which is supplied via the IO circuit 17, is temporarily stored in the page buffer 114.

Then, the write data inversion circuit 113 generates inverted write data in which the bits of the non-inverted write data stored in the page buffer 114 are inverted.

Further, the non-inverted write data and the inverted write data are supplied to the comparison circuit 117.

[Step S103]

The comparison circuit 117 compares the non-inverted write data and the read data corresponding to the address at which the non-inverted write data is overwritten, and calculates a number L1 of bits which require rewrite to “1” data.

[Step S104]

The comparison circuit 117 compares the inverted write data and the read data corresponding to the address at which the inverted write data is overwritten, and calculates a number L2 of bits which require rewrite to “1” data.

[Step S105]

The comparison circuit 117 determines whether number L1≤number L2. As described above, in the present embodiment, the power consumption at the time of writing “1” data is greater than the power consumption at the time of writing “0” data. Thus, from the standpoint of power consumption, it is desirable to reduce the number of times of write of “1” data. Hence, by comparing the number L1 and number L2, the comparison circuit 117 can determine which of the selection of the non-inverted write data and the selection of the inverted write data can make smaller the number of times of write of “1” data.

[Step S106]

When the comparison circuit 117 determines that number L1≤number L2 (step S105, YES), the comparison circuit 117 sets the header of the write data to “0” data which means non-inversion, and uses the non-inverted write data as the write data which is to be actually written to the memory cell array 111.

[Step S107]

When the comparison circuit 117 does not determine that number L1≤number L2 (step S105, NO), the comparison circuit 117 sets the header of the write data to “1” data which means inversion, and uses the inverted write data as the write data which is to be actually written to the memory cell array 111.

[Step S108]

The comparison circuit 117 confirms, on a bit-by-bit basis, whether the write data, which is to be actually written, and the read data are different or not.

[Step S109]

When the comparison circuit 117 executes write of bits which are determined to be different between the write data, which is to be actually written, and the read data, the comparison circuit 117 enables the write circuit 112 and causes the write circuit 112 to execute a write operation.

[Step S110]

When the comparison circuit 117 executes write of bits which are determined to be identical between the write data, which is to be actually written, and the read data, the comparison circuit 117 disables the write circuit 112 and prohibits the write circuit 112 from executing a write operation. Thereby, the power consumption at the write time is held down.

[Step S111]

The controller 16 determines whether the write is completed or not. When the controller 16 determines that the write is not completed (step S111, NO), the controller 16 repeats step S108. When the controller 16 determines that the write is completed (step S111, YES), the controller 16 finishes the write operation.

### <1-2-2> Concrete Example

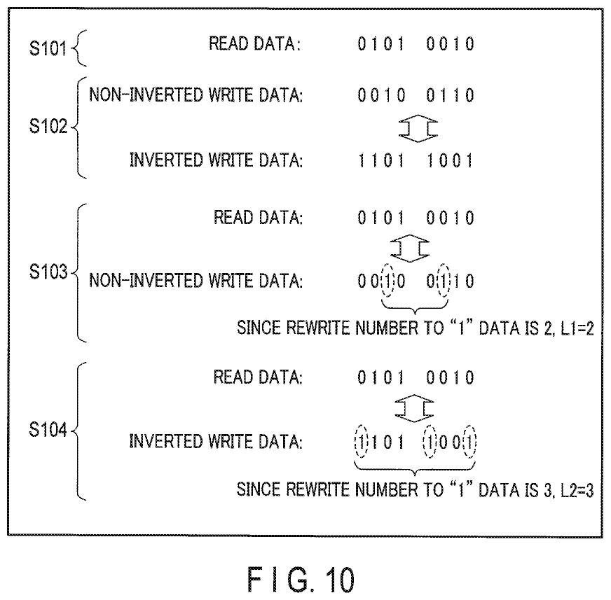

Next, referring to FIG. 10, a description is given of a concrete example of the write operation of the semiconductor memory device according to the first embodiment. For the purpose of simplicity, as regards the read data, non-inverted write data and inverted write data, the illustration of the header is omitted, and only the actual data is illustrated.

As illustrated in FIG. 10, it is assumed that the read data, which is read in step S101, is “0101 0010”.

It is assumed that the non-inverted write data in step S102 is “0010 0110”. The inverted write data becomes “1101 1001”, which is obtained by inverting the non-inverted write data “0010 0110”.

In step S103, the comparison circuit 117 compares the read data “0101 0010” and the non-inverted write data “0010 0110”, and calculates the number of bits requiring rewrite to “1” data in the read data. In this case, as encircled by broken lines in FIG. 10, “1” data at two locations are targets of rewrite. Thus, the number L1 is “2”.

In step S104, the comparison circuit 117 compares the read data “0101 0010” and the inverted write data “1101 1001”, and calculates the number of bits requiring rewrite to “1” data in the read data. In this case, as encircled by broken lines in FIG. 10, “1” data at three locations are targets of rewrite. Thus, the number L2 is “3”,

By the above, the comparison circuit 117 determines that number L1<number L2. Thus, the comparison circuit 117 executes step S106.

Subsequently, the semiconductor memory device 1 executes steps S108 to S111.

<1-3> Effects

According to the above-described embodiment, the semiconductor memory device compares the non-inverted write data, which is supplied from the controller, and the read data, thereby calculating the number L1 of the bits requiring rewrite to “1” data; compares the inverted write data, which is the inverted data of the non-inverted write data, and the read data, thereby calculating the number L2 of the bits requiring rewrite to “1” data; and compares the number L1 and the number L2. In the case of “number L1≤number L2”, the non-inverted write data is treated as the data which is to be actually written to the memory cell array 111. Not in the case of “number L1≤number L2”, the inverted write data is treated as the data which is to be actually written to the memory cell array 111.

There is a memory cell in which the direction of application of current or voltage is reversed in order to write “1” data or “0” data. In the case of such a memory cell, there is a case in which the power consumption by the application of current or voltage in a first direction differs from the power consumption by the application of current or voltage in a second direction. Alternatively, there is a case in which the limit number of times of write by the application of current or voltage in a first direction differs from the limit number of times of write by the application of current or voltage in a second direction. In such cases, it is desirable to suppress the write in the direction in which the power consumption is greater or the limit number of times of write is smaller.

In the present embodiment, as an example, it is assumed that the operation of write to “1” data is greater in power consumption. Thus, in this example, it is desirable to hold down the number of times of write to “1” data. In the present embodiment, two kinds of write data are prepared, and one of them, in which the number of rewrite to “1” data is smaller, is adopted as the write data. Thus, there can be provided a semiconductor memory device in which the number of times of write to “1” data can be held down and, as a result, the power consumption is held down.

### <2> Second Embodiment

A second embodiment will be described. In the second embodiment, a write operation different from the write operation of the first embodiment is described. The basic configuration and basic operation of the device according to the second embodiment are the same as those of the device according to the above-described embodiment. Thus, a description of the matters described in the above embodiment and a description of matters, which can easily be guessed from the above embodiment, are omitted.

<2-1> Configuration

A comparison circuit 117 according to the second embodiment will be described. Concretely, the comparison circuit 117 includes at least one of the following functions:
a function of generating a number M0 of “0” data of non-inverted write data, and a number M1 of “1” data of non-inverted write data,
a function of determining whether the number M1 is equal to or greater than the number M0,
a function of determining the header of write data,
a function of determining data which is to be actually written to the memory cell array 111, and
a function of comparing data that is to be actually written, and read data, enabling the write circuit 112 only at a time of writing different data, and disabling the write circuit 112 at a time of writing identical data.

<2-2> Operation

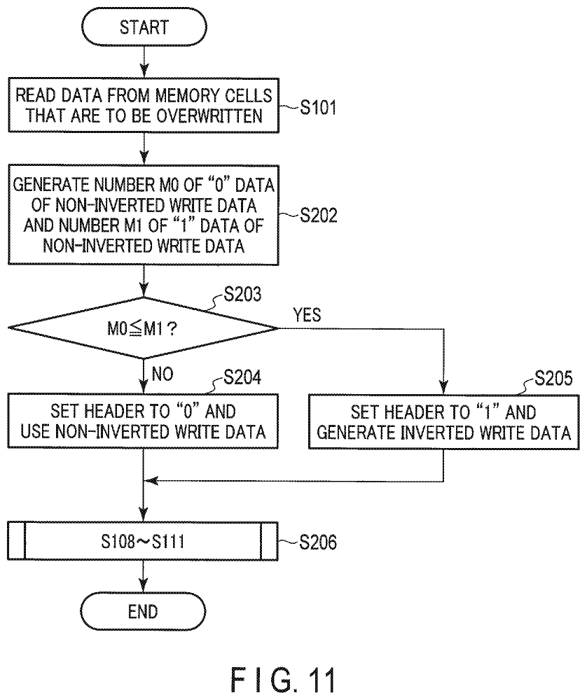

Hereinafter, referring to FIG. 11, a write operation of the semiconductor memory device according to the second embodiment will be described. A description of the operation, which was described in the flowchart of FIG. 8, is omitted.

To start with, step S101 is executed in the write operation of the semiconductor memory device according to the second embodiment.

[Step S202] After step S101, write data that is to be written to the memory cell array 111 is temporarily stored in the page buffer 114.

The comparison circuit 117 reads non-inverted write data from the page buffer 114, and generates a number M0 of “0” data of the non-inverted write data and a number M1 of “1” data of the non-inverted write data.

[Step S203]

The comparison circuit 117 determines whether number M0≤number M1. By comparing the number M0 and number M1, the comparison circuit 117 can estimate which of the selection of the non-inverted write data and the selection of the inverted write data can make smaller the number of times of write of “1” data. For example, not in the case of number M0≤number M1, it is understood that the number of “1” data is small in the non-inverted write data, and it can be estimated that the number of times of write to “1” data is small. Thus, by utilizing the non-inverted write data, the number of times of write to “1” data can be held down. On the other hand, in the case of number M0≤number M1, it is understood that the number of “1” data is large in the non-inverted write data, and it can be estimated that the number of times of write to “1” data is large. Thus, by utilizing inverted write data, the number of times of write to “1” data can be held down.

[Step S204]

When the comparison circuit 117 does not determine that number M0≤number M1 (step S203, NO), the comparison circuit 117 sets the header of the write data to “0” data which means non-inversion, and uses the non-inverted write data as the write data which is to be actually written to the memory cell array 111.

[Step S205]

When the comparison circuit 117 determines that number M0≤number M1 (step S203, YES), the comparison circuit 117 sets the header of the write data to “1” data which means inversion, and uses the inverted write data as the write data which is to be actually written to the memory cell array 111.

[Step S206]

The same operation as in steps S103 to S111 is executed.

<2-3> Effects

According to the above-described embodiment, the semiconductor memory device compares the number M0 of “0” data of non-inverted write data, which is supplied from the controller, and the number M1 of “1” data of the non-inverted write data. When the number M0 is greater than the number M1, the non-inverted write data is treated as the data which is to be actually written. When the number M1 is equal to or greater than the number M0, the inverted write data is treated as the data which is to be actually written. Thereby, the same effects as in the first embodiment can be obtained.

### <3> Third Embodiment

A third embodiment will be described. In the third embodiment, a write operation different from the write operation of each of the above-described embodiments is described. The basic configuration and basic operation of the device according to the third embodiment are the same as those of the device according to each of the above-described embodiments. Thus, a description of the matters described in the above embodiments and a description of matters, which can easily be guessed from the above embodiments, are omitted.

<3-1> Configuration

A comparison circuit 117 according to the third embodiment will be described. Concretely, the comparison circuit 117 includes at least one of the following functions:
a function of comparing read data and non-inverted write data, and generating a rewrite number N0 to “0” data and a rewrite number N1 to “1” data,
a function of determining whether the number N1 is equal to or greater than the number N0,
a function of determining the header of write data,
a function of determining data which is to be actually written to the memory cell array 111, and
a function of comparing data that is to be actually written, and read data, enabling the write circuit 112 only at a time of writing different data, and disabling the write circuit 112 at a time of writing identical data.

<3-2> Operation

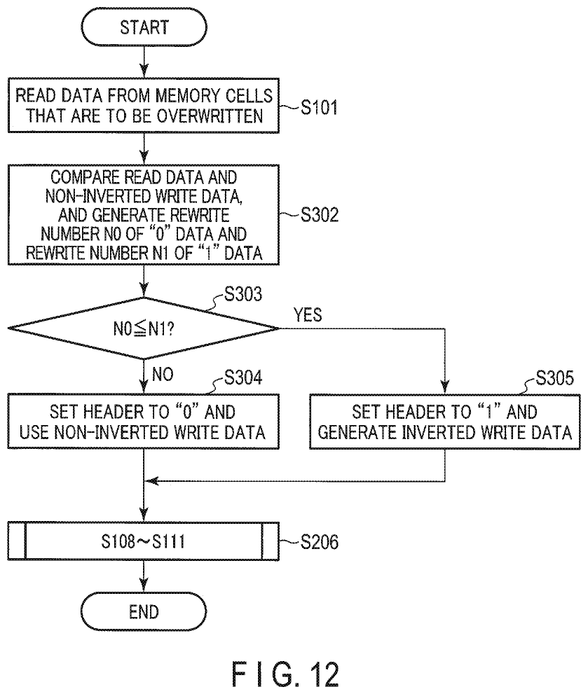

Hereinafter, referring to FIG. 12, a write operation of the semiconductor memory device according to the third embodiment will be described. A description of the operation, which was described in the flowcharts of FIG. 8 and FIG. 11, is omitted.

To start with, step S101 is executed in the write operation of the semiconductor memory device according to the third embodiment.

[Step S302]

After step S101, write data that is to be written to the memory cell array 111 is temporarily stored in the page buffer 114.

The comparison circuit 117 reads non-inverted write data from the page buffer 114. Further, the comparison circuit 117 compares the non-inverted write data and the read data corresponding to the address at which the non-inverted write data is overwritten, and generates a number N0 of bits which require rewrite to “0”-data, and a number N1 of bits which require rewrite to “1” data.

[Step S303]

The comparison circuit 117 determines whether number N0≤number N1. By comparing the number N0 and number N1, the comparison circuit 117 can estimate which of the selection of the non-inverted write data and the selection of inverted write data can make smaller the number of times of write of “1” data. For example, not in the case of number N0≤number N1, it is understood that the number of times of rewrite to “1” data is small in the non-inverted write data. Thus, by utilizing the non-inverted write data, the number of times of write to “1” data can be held down. On the other hand, in the case of number N0≤number N1, it is understood that the number of times of rewrite to “1” data is large in the non-inverted write data, and it can be estimated that the number of times of write to “1” data is large. Thus, by utilizing inverted write data, the number of times of write to “1” data can be held down.

[Step S304]

When the comparison circuit 117 does not determine that number N0≤number N1 (step S303, NO), the comparison circuit 117 sets the header of the write data to “0” data which means non-inversion, and uses the non-inverted write data as the write data which is to be actually written to the memory cell array 111.

[Step S305]

When the comparison circuit 117 determines that number N0≤number N1 (step S303, YES), the comparison circuit 117 sets the header of the write data to “1” data which means inversion, and uses the inverted write data as the write data which is to be actually written to the memory cell array 111.

After step S304 or S305, the same operation as in step S206 is executed.

<3-3> Effects

According to the above-described embodiment, the semiconductor memory device compares non-inverted write data, which is supplied from the controller, and read data, and compares the rewrite number N0 to “0” and the rewrite number N1 to “1”. When the number N0 is greater than the number N1, the non-inverted write data is treated as the data which is to be actually written. When the number N1 is equal to or greater than the number N0, the inverted write data is treated as the data which is to be actually written. Thereby, the same effects as in the first embodiment can be obtained.

### <4> Fourth Embodiment

A fourth embodiment will be described. In the fourth embodiment, a write operation different from the write operation of each of the above-described embodiments is described. The basic configuration and basic operation of the device according to the fourth embodiment are the same as those of the device according to each of the above-described embodiments. Thus, a description of the matters described in the above embodiments and a description of matters, which can easily be guessed from the above embodiments, are omitted.

<4-1> Configuration

A comparison circuit 117 according to the fourth embodiment will be described. Concretely, the comparison circuit 117 includes at least one of the following functions
a function of comparing read data and non-inverted write data, and generating a rewrite number N2,
a function of determining whether the number N2 is equal to or greater than a preset threshold number N3,
a function of comparing the read data and non-inverted write data, and generating a rewrite number N0 to “0” data and a rewrite number N1 to “1” data,
a function of determining whether the number N1 is equal to or greater than the number N0,
a function of determining the header of write data, m a function of determining data which is to be actually written to the memory cell array 111, and
a function of comparing the data that is to be actually written, and the read data, enabling the write circuit 112 only at a time of writing different data, and disabling the write circuit 112 at a time of writing identical data.

<4-2> Operation

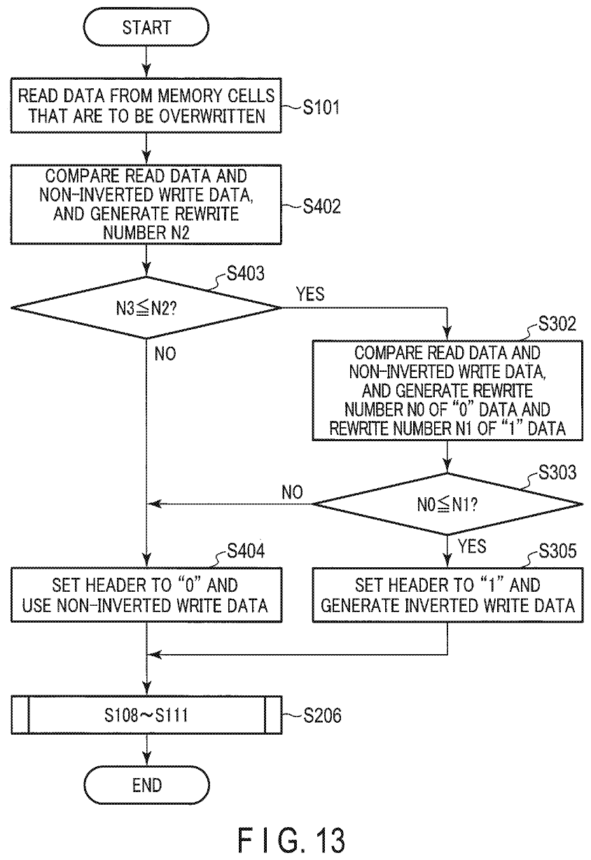

Hereinafter, referring to FIG. 13, a write operation of the semiconductor memory device according to the fourth embodiment will be described. A description of the operation, which was described in the flowcharts of FIG. 8, FIG. 11 and FIG. 12, is omitted.

To start with, step S101 is executed in the write operation of the semiconductor memory device according to the fourth embodiment.

[Step S402]

After step S101, write data that is to be written to the memory cell array 111 is temporarily stored in the page buffer 114.

The comparison circuit 117 reads non-inverted write data from the page buffer 114. Further, the comparison circuit 117 compares the non-inverted write data and the read data corresponding to the address at which the non-inverted write data is overwritten, and generates a number N2 of bits which require rewrite.

[Step S403]

The comparison circuit 117 determines whether number N3≤number N2. The number N3 is a preset value. The number N3 is stored in the comparison circuit 117, but may be stored, for example, in the memory cell array 111. When the comparison circuit 117 determines that number N3≤number N2 (step S403, YES), the comparison circuit 117 executes at least steps S302 and S303. By comparing the number N2 and number N3, the comparison circuit 117 can estimate which of the selection of the non-inverted write data and the selection of the inverted write data can make smaller the number of times of write of “1” data. For example, not in the case of number N3≤number N2, it is understood that the number of times of rewrite of data is small in the non-inverted write data. Thus, by utilizing the non-inverted write data, the number of times of write to “1” data can be held down.

[Step S404]

When the comparison circuit 117 does not determine that number N3≤number N2 (step S403, NO) or does not determine that number N0≤number N1 (step S303, NO), the comparison circuit 117 sets the header of the write data to “0” data which means non-inversion, and uses the non-inverted write data as the write data which is to be actually written to the memory cell array 111.

When the comparison circuit 117 determines that number N0≤number N1 (step S303, YES), the comparison circuit 117 executes step S305.

After step S404 or S305, the same operation as in step S206 is executed.

<4-3> Effects

According to the above-described embodiment, the semiconductor memory device generates the rewrite number N2, based on the non-inverted write data, which is supplied from the controller, and the read data, and determines whether the number N2 is equal to or greater than the preset threshold number N3. When the number N2 is greater than the number N3, the semiconductor memory device generates the rewrite number N0 to “0” data and the rewrite number N1 to “1” data, based on the non-inverted write data and read data. When the number N0 is greater than the number N1, or when the number N3 is greater than the number N2, the non-inverted write data is treated as the data which is to be actually written. When the number N1 is equal to or greater than the number N0, the inverted write data is treated as the data which is to be actually written. Thereby, the same effects as in the first embodiment can be obtained.

### <5> Fifth Embodiment

A fifth embodiment will be described. In the fifth embodiment, a write operation different from the write operation of each of the above-described embodiments is described. The basic configuration and basic operation of the device according to the fifth embodiment are the same as those of the device according to each of the above-described embodiments. Thus, a description of the matters described in the above embodiments and a description of matters, which can easily be guessed from the above embodiments, are omitted.

<5-1> Configuration

A comparison circuit 117 according to the fifth embodiment will be described. Concretely, the comparison circuit 117 includes at least one of the following functions:
a function of comparing read data and non-inverted write data, and generating a rewrite number N1 to “1” data,
a function of determining whether the number N1 is equal to or greater than a preset threshold number N3,
a function of determining the header of write data,
a function of determining data which is to be actually written to the memory cell array 111, and
a function of comparing the data that is to be actually written, and the read data, enabling the write circuit 112 only at a time of writing different data, and disabling the write circuit 112 at a time of writing identical data.

<5-2> Operation

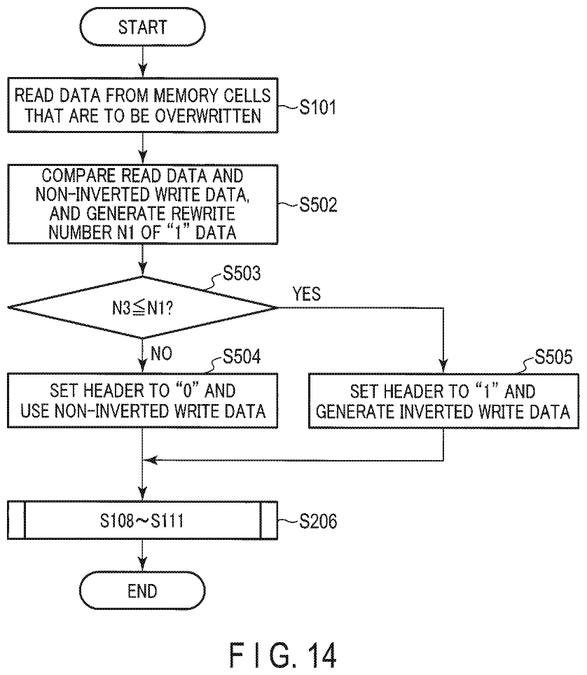

Hereinafter, referring to FIG. 14, a write operation of the semiconductor memory device according to the fifth embodiment will be described. A description of the operation, which was described in the flowcharts of FIG. 8, FIG. 11, FIG. 12 and FIG. 13, is omitted.

To start with, step S101 is executed in the write operation of the semiconductor memory device according to the fifth embodiment.

[Step S502]

After step S101, write data that is to be written to the memory cell array 111 is temporarily stored in the page buffer 114.

The comparison circuit 117 reads non-inverted write data from the page buffer 114. Further, the comparison circuit 117 compares the non-inverted write data and the read data corresponding to the address at which the non-inverted write data is overwritten, and generates a number N1 of bits which require rewrite to “1” data.

[Step S503]

The comparison circuit 117 determines whether number N3≤number N1. By comparing the number N3 and number N1, the comparison circuit 117 can estimate which of the selection of the non-inverted write data and the selection of the inverted write data can make smaller the number of times of write of “1” data. For example, not in the case of number N3≤number N1, it is understood that the number of times of rewrite to “1” data is small in the non-inverted write data. Thus, by utilizing the non-inverted write data, the number of times of write to “1” data can be held down. On the other hand, in the case of number N3≤number N1, it is understood that the number of times of rewrite to “1” data is large in the non-inverted write data, and it can be estimated that the number of times of write to “1” data is large. Thus, by utilizing inverted write data, the number of times of write to “1” data can be held down.

[Step S504]

When the comparison circuit 117 does not determine that number N3 number N1 (step S503, NO), the comparison circuit 117 sets the header of the write data to “0” data which means non-inversion, and uses the non-inverted write data as the write data which is to be actually written to the memory cell array 111.

[step S505]

When the comparison circuit 117 determines that number N3 number N1 (step S503, YES), the comparison circuit 117 sets the header of the write data to “1” data which means inversion, and uses the inverted write data as the write data which is to be actually written to the memory cell array 111.

<5-3> Effects

According to the above-described embodiment, the semiconductor memory device generates the rewrite number N1 to “1” data, based on the non-inverted write data, which is supplied from the controller, and the read data, and determines whether the number N1 is equal to or greater than the preset threshold number N3. When the number N3 is greater than the number N1, the non-inverted write data is treated as the data which is to be actually written. When the number N1 is equal to or greater than the number N3, the inverted write data is treated as the data which is to be actually written. Thereby, the same effects as in the first embodiment can be obtained.

### <6> Others

In the above-described embodiments, the example is described in which a field-effect transistor (three terminal type switching element) is used as the selector (switching element) of the memory cell. The selector may be, for example, an two-terminal type switching element. When a voltage applied between two terminals is less than a threshold, the switching element is in a “high-resistance” state, for example, in an electrically non-conductive state. When the voltage applied between the two terminals is equal to or greater than the threshold, the switching element transitions to a “low-resistance” state, for example, in an electrically conductive state. In addition, the switching element may have this function even when the voltage is of either polarity. For example, the switching element may include at least one chalcogen element selected from the group consisting of Te, Se and S. Alternatively, the switching element may include a chalcogenide which is a compound including the chalcogen element. Besides, the switching element may include at least one element selected from the group consisting of B, Al, Ga, In, C, Si, Ge, Sn, As, P and Sb.

This inter-two-terminal switching element is connected to the magnetoresistance effect element via two contact plugs, as in the above-described embodiments. Of the two contact plugs, the contact plug on the side of the magnetoresistance effect element includes copper. A conductive layer (e.g. a layer including tantalum) may be provided between the magnetoresistance effect element and the contact plug including copper.

In each of the above-described embodiments, the case was described in which the core 11 is divided into regions according to the volumes of the MTJ elements, and the regions are selectively used. The above-described areas and arrangement of the regions are merely examples, and are changeable as appropriate.

In each of the above-described embodiments, the case was described in which the first example is applied as the configuration of the memory cell MC. However, in each of the above embodiments, the second example may be applied as the configuration of the memory cell MC, and the same effects as in the case of applying the first example can be obtained.

In each of the above-described embodiments, the memory system or the semiconductor memory device may be a package. The term “connection” in each of the embodiments includes a state of an indirect connection with some other element, such as a transistor or a resistor, intervening.

Here, the MRAM was described by way of example, which stores data by using the magnetoresistance effect element (Magnetic Tunnel Junction (MTJ) element) as a resistance change-type element, but the embodiments are not limited to this.

For example, the embodiments are applicable to a semiconductor memory device including an element which stores data by utilizing a resistance change, for example, a resistance change-type memory similar to the MRAM, such as a ReRAM or a PCRAM.

Furthermore, the embodiments are applicable to a semiconductor memory device including an element which can store data by a resistance change due to application of current or voltage, or can read stored data by converting a resistance difference due to a resistance change to a current difference or a voltage difference, regardless of whether the semiconductor memory device is a volatile memory or a nonvolatile memory.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell capable of storing data;
a storage area including the memory cells; and
a controller configured:
to read data from the physical address in which write data will be write;
to compare the read data and the non-inverted write data, and to calculate a number n1 of bits which require rewrite to first data when executing the write;
to compare the read data and the inverted write data, and to calculate a number n2 of bits which require rewrite to the first data when executing the write;
to compare the number n1 and the number n2;
if n1≤n2, to write the non-inverted write data to the storage area; and
if n1>n2, to write the inverted write data to the storage area.

2. The semiconductor memory device of claim 1, wherein the controller is configured:
to write first information, which indicates that the non-inverted write data is written to the storage area, to the storage area when the non-inverted write data is written to the storage area; and
to write second information, which indicates that the inverted write data is written to the storage area, to the storage area when the inverted write data is written to the storage area.

3. The semiconductor memory device of claim 2, wherein the controller is configured:
to output, when data which is read from the storage area includes the first information, the data which is read; and
to invert and output, when data which is read from the storage area includes the second information, the data which is read.

4. The semiconductor memory device of claim 1, wherein when the controller executes writes of data to the storage area, the controller is configured to not execute the write of data when the read data stored in the memory cells to which write is executed is identical to data which is written.

5. The semiconductor memory device of claim 1, wherein power consumption required for write of the first data to the memory cells is greater than power consumption required for write of inverted data of the first data to the memory cells.

6. A semiconductor memory device comprising:
a memory cell capable of storing data;
a storage area including the memory cells; and
a controller configured:
to read data from the physical address in which write data will be write;
to calculate a number n1 of non-inverted write data and a s number n2 of inverted write data in the non-inverted write data;
to compare the number n1 and the number n2;
if n1>n2, to write the non-inverted write data to the storage area; and
if n1≤n2, to write inverted write data to the storage area.

7. The semiconductor memory device of claim 6, wherein the controller is configured:
to write first information, which indicates that the non-inverted write data is written to the storage area, to the storage area when the non-inverted write data is written to the storage area; and
to write second information, which indicates that the inverted write data is written to the storage area, to the storage area when the inverted write data is written to the storage area.

8. The semiconductor memory device of claim 7, wherein the controller is configured:
to output, when data which is read from the storage area includes the first information, the data which is read; and
to invert and output, when data which is read from the storage area includes the second information, the data which is read.

9. The semiconductor memory device of claim 6, wherein when the controller executes writes of data to the storage area, the controller is configured to not execute the write of data when the read data stored in the memory cells to which write is executed is identical to data which is written.

10. The semiconductor memory device of claim 6, wherein power consumption required for write of the first data to the memory cells is greater than power consumption required for write of inverted data of the first data to the memory cells.

11. A semiconductor memory device comprising:
a memory cell capable of storing data;
a storage area including the memory cells; and
a controller configured:
to read data from the physical address in which write data will be write;
to compare the non-inverted write data and the read data, and to calculate a number n1 of bits which require rewrite when executing the write;
to compare the number n1 and a number n2 stored in the storage area;
if n2>n1, to write the non-inverted write data to the storage area;
if n2≤n1, to compare the non-inverted write data and the read data, and to calculate a number n3 of bits which require rewrite of first data when executing the write, and a number n4 of bits which require rewrite of second data when executing the write;
to compare the number n3 and the number n4;
if n3>n4, to write the non-inverted write data to the storage area; and
if n3≤n4, to write inverted write data, which is inverted data of the non-inverted write data, to the storage area.

12. The semiconductor memory device of claim 11, wherein the controller is configured:
to write first information, which indicates that the non-inverted write data is written to the storage area, to the storage area when the non-inverted write data is written to the storage area; and
to write second information, which indicates that the inverted write data is written to the storage area, to the storage area when the inverted write data is written to the storage area.

13. The semiconductor memory device of claim 12, wherein the controller is configured:
to output, when data which is read from the storage area includes the first information, the data which is read; and
to invert and output, when data which is read from the storage area includes the second information, the data which is read.

14. The semiconductor memory device of claim 11, wherein when the controller executes writes of data to the storage area, the controller is configured to not execute the write of data when the read data stored in the memory cells to which write is executed is identical to data which is written.

15. The semiconductor memory device of claim 11, wherein power consumption required for write of the first data to the memory cells is greater than power consumption required for write of inverted data of the first data to the memory cells.
